(19) United States
(12) Patent Application Publication
(10) Pub. No.: US 2022/0251709 A1
(43) Pub. Date: Aug. 11, 2022

(54) SUBSTRATE PROCESSING METHOD AND SUBSTRATE PROCESSING APPARATUS

(71) Applicant: Tokyo Electron Limited, Tokyo (JP)

(72) Inventor: Takafumi Niwa, Kikuchi-gun, Kumamoto (JP)

(21) Appl. No.: 17/596,385

(22) PCT Filed: Jun. 4, 2020
(86) PCT No.: PCT/JP2020/022189

§ 371 Date: Dec. 9, 2021

(30) Foreign Application Priority Data
Jun. 17, 2019 (JP) 2019-112114

(51) Int. Cl. C23C 18/18; C23C 18/31; C23C 18/16

(52) U.S. Cl. CPC C23C 18/18; C23C 18/1689; C23C 18/1678; C23C 18/31

(57) ABSTRACT

A substrate processing method includes activating, accumulating, forming a plating film, performing a post-processing and drying. In the activating, a plating liquid L1 is activated by heating and maintaining the plating liquid at a preset temperature. In the accumulating, the activated plating liquid is accumulated on a substrate W. In the forming of the plating film, the plating film is formed on the substrate by electroless plating while heating the substrate on which the plating liquid is accumulated. In the performing of the post-processing, the post-processing is performed on the substrate on which the plating film is formed. In the drying, the substrate after being subjected to the post-processing is dried. Activating the plating liquid for the substrate to be processed next is performed in parallel with the forming of the plating film, the performing of the post-processing, and the drying upon the substrate being processed currently.

### TECHNICAL FIELD

The various aspects and embodiments described herein pertain generally to a substrate processing method and a substrate processing apparatus.

### BACKGROUND

Conventionally, in a semiconductor manufacturing process, a plating processing is used as a way to fill a metal such as copper in a recess such as a trench or a via.

### PRIOR ART DOCUMENT

Patent Document 1: Japanese Patent Laid-open Publication No. 2018-003097

### DISCLOSURE OF THE INVENTION

### Problems to be Solved by the Invention

Exemplary embodiments provide a technique enabling to improve a throughput of a series of substrate processings including a plating processing.

### Means for Solving the Problems

In an exemplary embodiment, a substrate processing method includes activating, accumulating a liquid, forming a plating film, performing a post-processing and drying. In the activating, a plating liquid is activated by previously heating and maintaining the plating liquid at a preset temperature. In the accumulating of the liquid, the activated plating liquid is accumulated on a substrate. In the forming of the plating film, the plating film is formed on the substrate by electroless plating while heating the substrate on which the plating liquid is accumulated. In the performing of the post-processing, the post-processing is performed with a liquid on the substrate on which the plating film is formed. In the drying, the substrate after being subjected to the post-processing is dried. Activating the plating liquid for the substrate to be processed next is performed in parallel with the forming of the plating film, the performing of the post-processing, and the drying of the substrate upon the substrate being processed currently.

### Effect of the Invention

According to the exemplary embodiments, it is possible to improve the throughput of the series of substrate processings including the plating processing.

### BRIEF DESCRIPTION OF THE DRAWINGS

FIG. 1 is a diagram illustrating a configuration of a substrate processing apparatus according to an exemplary embodiment.

FIG. 2 is a diagram illustrating a configuration of a plating unit according to the exemplary embodiment.

FIG. 3 is a diagram illustrating a configuration of a plating liquid supply according to the exemplary embodiment.

FIG. 4 is a flowchart showing a sequence of processings performed by the substrate processing apparatus.

FIG. 5 is an explanatory diagram of an activation processing according to the exemplary embodiment.

FIG. 6 is a flowchart illustrating a sequence of an adjustment time setting processing according to the exemplary embodiment.

FIG. 7 is a diagram illustrating an example of the adjustment time setting processing according to the exemplary embodiment.

FIG. 8 is an explanatory diagram of a dummy adjustment processing according to the exemplary embodiment.

### DETAILED DESCRIPTION

Hereinafter, exemplary embodiments for a substrate processing method and a substrate processing apparatus according to the present disclosure (hereinafter, referred to as “exemplary embodiments”) will be described in detail with reference to the accompanying drawings. Further, it should be noted that the substrate processing method and the substrate processing apparatus according to the present disclosure are not limited by the exemplary embodiments. Furthermore, unless processing contents are contradictory, the various exemplary embodiments can be appropriately combined. In addition, in the various exemplary embodiments to be described below, same parts will be assigned same reference numerals, and redundant description will be omitted.

Further, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “0 direction.”

<Configuration of Substrate Processing Apparatus>

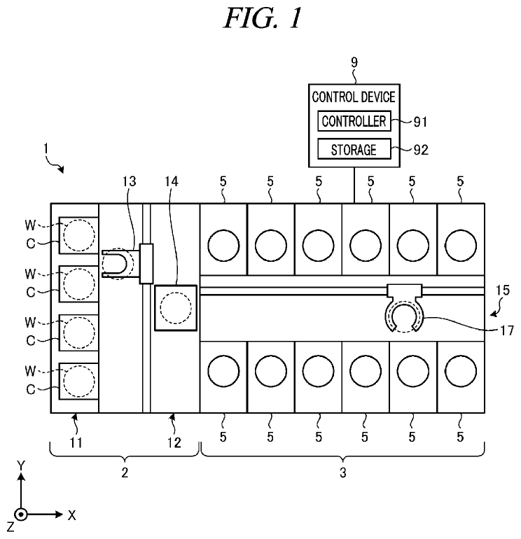

FIG. 1 is a diagram illustrating a configuration of a substrate processing apparatus according to an exemplary embodiment. As depicted in FIG. 1, a substrate processing apparatus 1 includes a carry-in/out station 2 and a processing station 3. The carry-in/out station 2 and the processing station 3 are provided adjacent to each other.

The carry-in/out station 2 includes a carrier placing table 11 and a transfer section 12. A plurality of cassettes C, each of which accommodates horizontally therein a multiple number of substrates, i.e., semiconductor wafers (hereinafter, simply referred to as substrates W) in the present exemplary embodiment, is disposed on the carrier placing table 11.

On the carrier placing table 11, a plurality of load ports are arranged adjacent to the transfer section 12, and the carriers C are respectively placed on the load ports.

The transfer section 12 is provided adjacent to the carrier placing table 11, and incorporates therein a substrate transfer device 13 and a delivery unit 14. The substrate transfer device 13 is equipped with a wafer holding mechanism configured to hold the substrate W. Further, the substrate transfer device 13 is configured to be movable in horizontal and vertical directions and pivotable around a vertical axis, and it serves to transfer the substrate W between the carrier C and the delivery unit 14 by using the wafer holding mechanism.

The processing station 3 is provided adjacent to the transfer section 12. The processing station 3 includes a transfer section 15 and a plurality of plating units 5. These multiple plating units 5 are arranged on both sides of the transfer section 15. A configuration of the plating unit 5 will be described later.

The transfer section 15 has a substrate transfer device 17 therein. The substrate transfer device 17 is equipped with a wafer holding mechanism configured to hold the substrate W. In addition, the substrate transfer device 17 is configured to be movable in horizontal and vertical directions and pivotable around a vertical axis, and it serves to transfer the substrate W between the delivery unit 14, a pre-processing unit 4 and the plating unit 5 by using the wafer holding mechanism.

Further, the substrate processing apparatus 1 is equipped with a control device 9. The control device 9 is, for example, a computer, and includes a controller 91 and a storage 92. The storage 92 stores therein a program for controlling various processings performed in the substrate processing apparatus 1. The controller 91 controls an operation of the substrate processing apparatus 1 by reading and executing the program stored in the storage 92.

The program may be recorded in a computer-readable recording medium, and may be installed from this recording medium to the storage 92 of the control device 9. The computer-readable recording medium may be, by way of non-limiting example, a hard disk (HD), a flexible disk (FD), a compact disk (CD), a magnet optical disk (MO), a memory card, or the like.

In the substrate processing apparatus 1 configured as described above, the substrate transfer device 13 of the carry-in/out station 2 first takes out the substrate W from the carrier C placed on the carrier placing table 11, and places the taken substrate W in the delivery unit 14. The substrate W placed in the delivery unit 14 is transferred from the delivery unit 14 to the plating unit 5 by the substrate transfer device 17 of the processing station 3, and is processed by the plating unit 5. Specifically, the substrate W has a recess such as a trench or a via in a surface thereof, and the plating unit 5 fills a metal in this recess by an electroless plating method.

The substrate W processed by the plating unit 5 is taken out of the plating unit 5 by the substrate transfer device 17 and placed in the delivery unit 14. Then, the substrate W placed in the delivery unit 14, which is finished with the processing, is returned to the carrier C of the carrier placing table 11 by the substrate transfer device 13.

<Configuration of Plating Unit>

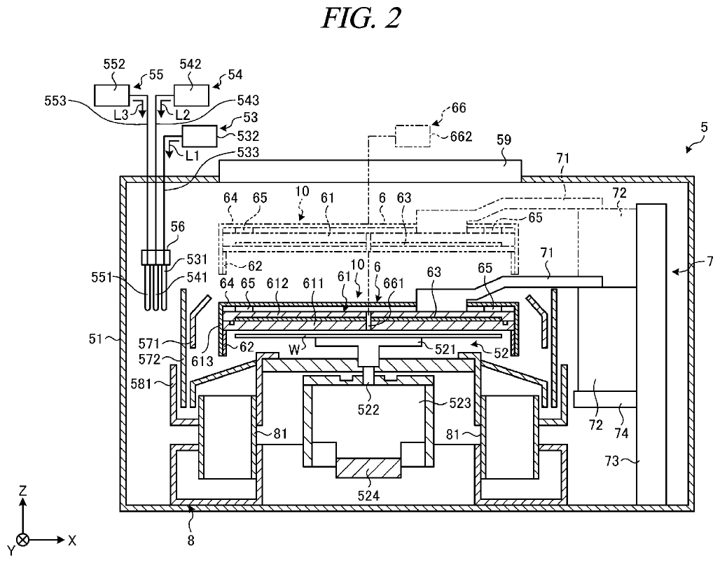

Now, referring to FIG. 2, the configuration of the plating unit 5 will be explained. FIG. 2 is a diagram illustrating the configuration of the plating unit 5 according to the exemplary embodiment.

The plating unit 5 is configured to perform a liquid processing including an electroless plating processing. This plating unit 5 includes a chamber 51, a substrate holder 52 disposed in the chamber 51 and configured to hold the substrate W horizontally, and a plating liquid supply 53 configured to supply a plating liquid L1 onto a top surface (front surface) of the substrate W held by the substrate holder 52.

In the present exemplary embodiment, the substrate holder 52 has a chuck member 521 configured to vacuum-attract a bottom surface (rear surface) of the substrate W. This chuck member 521 is of a so-called vacuum chuck type.

A rotation motor 523 (rotation drive unit) is connected to the substrate holder 52 via a rotation shaft 522. If this rotation motor 523 is driven, the substrate holder 52 is rotated along with the substrate W. The rotation motor 523 is supported on a base 524 fixed to the chamber 51. Further, a heating source such as a heater is not provided in the substrate holder 52.

The plating liquid supply 53 includes a plating liquid nozzle 531 configured to discharge the plating liquid L1 onto the top surface of the substrate W held by the substrate holder 52, and a plating liquid source 532 that stores therein the plating liquid L1 to be supplied to the plating liquid nozzle 531. The plating liquid nozzle 531 is held by a nozzle arm 56, and is configured to be movable.

The plating liquid L1 is an autocatalytic (reduction) plating liquid for electroless plating. The plating liquid L1 contains, by way of non-limiting example, a metal ion and a reducing agent. The metal ion contained in the plating liquid L1 may be, but not limited to, a cobalt (Co) ion, a nickel (Ni) ion, a tungsten (W) ion, a copper (Cu) ion, a palladium (Pd) ion, a gold (Au) ion, a ruthenium (Ru) ion, or the like. The reducing agent contained in the plating liquid L1 may be hypophosphorous acid, dimethylamineborane, glyoxylic acid, or the like. A plating film formed by a plating processing using the plating liquid L1 may be, by way of non-limiting example, CoWB, CoB, CoWP, CoWBP, NiWB, NiB, NiWP, NiWBP, Cu, Pd, Ru, or the like. Further, the plating film may be formed in a single layer or in two or more layers. When the plating film has a two-layer structure, it may have a layer structure of CoWB/CoB or Pd/CoB in sequence from a base metal layer (seed layer) side.

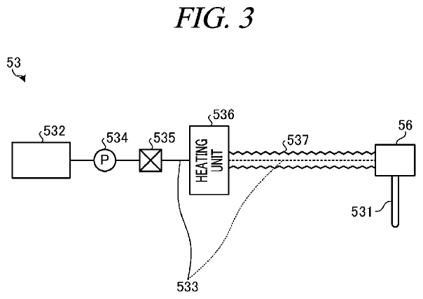

Here, a specific configuration of the plating liquid supply 53 will be described with reference to FIG. 3. FIG. 3 is a diagram showing the configuration of the plating liquid supply 53 according to the exemplary embodiment.

As shown in FIG. 3, the plating liquid supply 53 further includes a pump 534, a valve 535, a heating unit 536, and a heat retaining unit 537. The pump 534, the valve 535, the heating unit 536 and the heat retaining unit 537 are provided on a plating liquid line 533 in this order from the upstream side (the plating liquid supply 532 side).

The plating liquid source 532 is, for example, a tank that stores the plating liquid L1 therein. The plating liquid L1 of a room temperature is stored in the plating liquid source 532. The pump 534 is configured to send the plating liquid L1 stored in the plating liquid source 532 into the plating liquid line 533. The valve 535 is configured to open or close the plating liquid line 533.

The heating unit 536 is, for example, a heat exchanger, and configured to heat the plating liquid L1 flowing in the plating liquid line 533 to a set temperature. The heat retaining unit 537 is provided to cover the plating liquid line 533 at the downstream of the heating unit 536, and it serves to maintain the plating liquid L1 at the set temperature until the plating liquid L1 heated to the set temperature by the heating unit 536 is discharged from the plating liquid nozzle 531. For example, the heat retaining unit 537 brings a heat transfer medium heated to the set temperature into contact with the plating liquid line 533 at the downstream of the heating unit 536, thus allowing the plating liquid L1 flowing in the plating liquid line 533 at the downstream of the heating unit 536 to be maintained at the set temperature.

As described above, the plating liquid supply 53 supplies the plating liquid L1 heated to the set temperature from the plating liquid nozzle 531 onto the top surface of the substrate W. Here, the set temperature is in the range from, e.g., 55° C. to 75° C., more desirably, in the range from 60° C. to 70° C.

As depicted in FIG. 2, the plating unit 5 further includes a cleaning liquid supply 54 configured to supply a cleaning liquid L2 onto the front surface of the substrate W held by the substrate holder 52, and a rinse liquid supply 55 configured to supply a rinse liquid L3 onto the front surface of the substrate W.

The cleaning liquid supply 54 supplies the cleaning liquid L2 onto the substrate W being held and rotated by the substrate holder 52, and pre-cleans a seed layer formed on the substrate W. This cleaning liquid supply 54 includes a cleaning liquid nozzle 541 configured to discharge the cleaning liquid L2 onto the substrate W held by the substrate holder 52, and a cleaning liquid source 542 that supplies the cleaning liquid L2 to the cleaning liquid nozzle 541. The cleaning liquid source 542 is configured to supply the cleaning liquid L2, which is heated or temperature-controlled to a predetermined temperature as will be described later, to the cleaning liquid nozzle 541 via a cleaning liquid line 543. The cleaning liquid nozzle 541 is held by the nozzle arm 56 and is configured to be movable along with the plating liquid nozzle 531.

As the cleaning liquid L2, dicarboxylic acid or tricarboxylic acid is used. By way of example, an organic acid such as malic acid, succinic acid, malonic acid, oxalic acid, glutaric acid, adipic acid or tartaric acid may be used as the dicarboxylic acid. Further, an organic acid such as citric acid, for example, may be used as the tricarboxylic acid.

The rinse liquid supply 55 includes a rinse liquid nozzle 551 configured to discharge the rinse liquid L3 onto the substrate W held by the substrate holder 52, and a rinse liquid source 552 that supplies the rinse liquid L3 to the rinse liquid nozzle 551. The rinse liquid nozzle 551 is held by the nozzle arm 56 and is configured to be movable along with the plating liquid nozzle 531 and the cleaning liquid nozzle 541. Further, the rinse liquid source 552 is configured to supply the rinse liquid L3 to the rinse liquid nozzle 551 via a rinse liquid line 553. As the rinse liquid L3, DIW (deionized water), for example, may be used.

A non-illustrated nozzle moving mechanism is connected to the nozzle arm 56 that holds the plating liquid nozzle 531, the cleaning liquid nozzle 541, and the rinse liquid nozzle 551 described above. This nozzle moving mechanism moves the nozzle arm 56 in a horizontal direction and a vertical direction. More specifically, the nozzle arm 56 is configured to be moved by the nozzle moving mechanism between a discharge position where a processing liquid (the plating liquid L1, the cleaning liquid L2, or the rinse liquid L3) is discharged onto the substrate W and a retreat position retreated from the discharge position. Here, the discharge position is not particularly limited as long as the processing liquid can be supplied to a certain position on the front surface of the substrate W. For example, it may be appropriate to set a position where the processing liquid can be supplied to the center of the substrate Was the discharge position. The discharge position of the nozzle arm 56 may be different when the plating liquid L1 is supplied, when the cleaning liquid L2 is supplied, and when the rinse liquid L3 is supplied onto the substrate W. The retreat position is a position within the chamber 51 which is not overlapped with the substrate W when viewed from above, and it is a position far from the discharge position. When the nozzle arm 56 is placed at the retreat position, interference between the nozzle arm 56 and a lid 6 being moved can be avoided.

In addition to the plating liquid nozzle 531, the cleaning liquid nozzle 541 and the rinse liquid nozzle 551, the plating unit 5 may be further equipped with, for example, a nozzle through which a volatile organic solvent such as IPA (isopropyl alcohol) is supplied onto the substrate W.

A cup 571 is provided around the substrate holder 52. This cup 571 is formed to have a ring shape when viewed from above. The cup 571 receives the processing liquid scattered from the substrate W when the substrate W is rotated, and guides the received processing liquid into a drain duct 581. An atmosphere blocking cover 572 is provided around the cup 571 to suppress the atmosphere around the substrate W from being diffused into the chamber 51. The atmosphere blocking cover 572 is formed in a cylindrical shape so as to extend in the vertical direction and has an open upper end. The lid 6 to be described later is configured to be inserted into this atmosphere blocking cover 572 from above.

In the present exemplary embodiment, the substrate W held by the substrate holder 52 is covered by the lid 6. This lid 6 has a ceiling member 61 and a sidewall member 62 extending downwards from the ceiling member 61.

The ceiling member 61 includes a first ceiling plate 611 and a second ceiling plate 612 provided on the first ceiling plate 611. A heater 63 (heating unit) is disposed between the first ceiling plate 611 and the second ceiling plate 612. The first ceiling plate 611 and the second ceiling plate 612 hermetically seal the heater 63 so that the heater 63 does not come into contact with the processing liquid such as the plating liquid L1. More specifically, a seal ring 613 is provided around the heater 63, and the heater 63 is sealed by the seal ring 613. Appropriately, the first ceiling plate 611 and the second ceiling plate 612 have corrosion resistance against the processing liquid such as the plating liquid L1, and may be formed of, for example of, an aluminum alloy. Moreover, in order to improve the corrosion resistance, the first ceiling plate 611, the second ceiling plate 612 and the sidewall member 62 may be coated with Teflon (registered trademark).

A lid moving mechanism 7 is connected to the lid 6 via a lid arm 71. The lid moving mechanism 7 is configured to move the lid 6 in the horizontal direction and the vertical direction. More specifically, the lid moving mechanism 7 includes a revolving motor 72 configured to move the lid 6 in the horizontal direction; and a cylinder 73 (distance adjuster) configured to move the lid 6 in the vertical direction. The revolving motor 72 is mounted on a support plate 74 which is configured to be movable in the vertical direction with respect to the cylinder 73. Instead of the cylinder 73, an actuator (not shown) including a motor and a ball screw may be used.

The revolving motor 72 of the lid moving mechanism 7 moves the lid 6 between an upper position above the substrate W held by the substrate holder 52 and a retreat position retreated from the upper position. Here, the upper position is a position facing the substrate W held by the substrate holder 52 at a relatively large distance, and it is a position overlapping with the substrate W when viewed from above. The retreat position is a position within the chamber 51 that is not overlapped with the substrate W when viewed from above. When the lid 6 is located at the retreat position, interference between the lid 6 and the nozzle arm 56 is avoided when the nozzle arm 56 is being moved. A rotation axis of the revolving motor 72 extends in the vertical direction, and the lid 6 is configured to be revolved between the upper position and the retreat position in the horizontal direction.

The cylinder 73 of the lid moving mechanism 7 is configured to move the lid 6 up and down, thus adjusting the distance between the first ceiling plate 611 of the ceiling member 61 and the substrate W on which the plating liquid L1 is supplied. More specifically, the cylinder 73 locates the lid 6 at a lower position (a position indicated by a solid line in FIG. 2) and an upper position (a position indicated by a dashed double-dotted line in FIG. 2).

In the present exemplary embodiment, the heater 63 is driven to heat the plating liquid L1 on the substrate W or the substrate holder 52 when the lid 6 is located at the aforementioned lower position.

An inert gas (for example, a nitrogen (N₂) gas) is supplied to the inside of the lid 6 by an inert gas supply 66. The inert gas supply 66 includes a gas nozzle 661 configured to discharge the inert gas to the inside of the lid 6, and an inert gas source 662 configured to supply the inert gas to the gas nozzle 661. Here, the gas nozzle 661 is provided at the ceiling member 61 of the lid 6, and it discharges the inert gas toward substrate W in the state that the substrate W is covered by the lid 6.

The ceiling member 61 and the sidewall member 62 of the lid 6 are covered with a lid cover 64. This lid cover 64 is disposed on the second ceiling plate 612 of the lid 6 with a plurality of supports 65 therebetween. That is, the supports 65 are provided on the second ceiling plate 612, protruding upwards from a top surface of the second ceiling plate 612, and the lid cover 64 is disposed on the supports 65. The lid cover 64 is configured to be movable in the horizontal direction and the vertical direction together with the lid 6. Furthermore, in order to suppress heat within the lid 6 from leaking to the vicinity thereof, it is desirable that the lid cover 64 has higher heat insulating property than the ceiling member 61 and the sidewall member 62. For example, it is desirable that the lid cover 64 is formed of a resin material, and, more desirably, the resin material has heat resistance.

As stated above, in the present exemplary embodiment, the lid cover 64 and the lid 6 equipped with the heater 63 are configured as one body. The lid 6 and the lid cover 64 constitute a cover unit 10 configured to cover the substrate holder 52 or the substrate W when placed at the lower position.

A fan filter unit 59 (gas supply) configured to supply clean air (gas) to the vicinity of the lid 6 is provided at an upper portion of the chamber 51. The fan filter unit 59 supplies air into the chamber 51 (in particular, into the atmosphere blocking cover 572), and the supplied air flows toward an exhaust pipe 81. A downflow of this air flowing downwards is formed around the lid 6, and a gas vaporized from the processing liquid such as the plating liquid L1 flows toward the exhaust pipe 81 along this downflow. Accordingly, the gas vaporized from the processing liquid is suppressed from rising and diffusing into the chamber 51.

The gas supplied from the above-described fan filter unit 59 is exhausted by an exhaust mechanism 8.

In the plating unit 5 having the above-described configuration, operations of the substrate holder 52, the heater 63 (heating unit) and the plating liquid supply 53 are controlled by the controller 91. The controller 91 controls the heater 63 (heating unit) to heat the substrate holder 52 to 50° C. or higher before the substrate W is attracted to and held by the substrate holder 52. For example, if the temperature of the plating liquid L1 is in the range from 55° C. to 75° C. at the moment the plating liquid L1 is discharged, it is desirable to set the temperature of the substrate holder 52 to be in the range from 50° C. to 80° C.

<Specific Operation of Substrate Processing Apparatus>

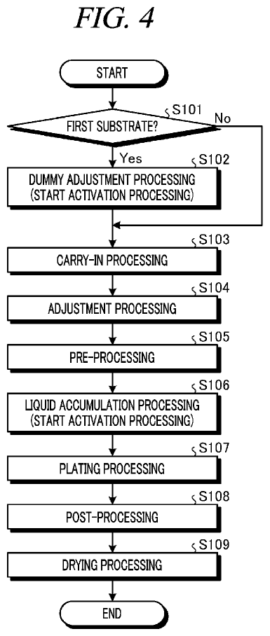

Now, a specific operation of the above-described substrate processing apparatus 1 will be explained with reference to FIG. 4. FIG. 4 is a flowchart showing a sequence of processings performed by the substrate processing apparatus 1 according to the exemplary embodiment. Further, the series of processings shown in FIG. 4 are performed under the control of the controller 91.

Furthermore, in the series of processings shown in FIG. 4, the heating unit 536 and the heat retaining unit 537 are set to be always capable of heating the plating liquid L1 flowing in the plating liquid line 533 and keeping it warm.

As depicted in FIG. 4, the controller 91 determines whether or not the substrate W to be processed currently is the first one among a plurality of substrates W to be successively processed (process S101). For example, assume that the substrate W to be currently processed in a certain plating unit 5 is the first one to be processed in this plating unit 5 among the plurality of substrates W (substrates W corresponding to one lot) accommodated in one carrier C. In this case, the controller 91 makes a determination that the substrate W is the first one among the plurality of substrates W to be successively processed.

If it is determined in the process S101 that the substrate W to be currently processed is the first one among the plurality of substrates W to be processed sequentially (process S101, Yes), a dummy adjustment processing is performed in the plating unit 5 (process S102). In the dummy adjustment processing, the substrate W stands by in front of the plating unit 5 for a set time while being held by the substrate transfer device 17, for example. That is, a carry-in of the substrate W into the plating unit 5 is delayed by the set time.

Further, in the plating unit 5, an activation processing is started in parallel with the dummy adjustment processing. For example, the activation processing may be started at the time when the dummy adjustment processing is begun. The activation processing is a process of activating the plating liquid by heating and maintaining the plating liquid L1 at a predetermined temperature. The activation processing here is a process of activating the plating liquid L1 used for the substrate W to be currently processed.

Specifically, the plating unit 5 controls the pump 534 and the valve 535 to send a predetermined amount of the plating liquid L1 of the room temperature stored in the plating liquid source 532 into the plating liquid line 533 at the downstream of the valve 535.

Although a part of the plating liquid L1 sent to the plating liquid line 533 on the downstream side of the valve 535 is discharged from the plating liquid nozzle 531, a part of the rest of the plating liquid L1 remains in the plating liquid line 533 on the downstream side of the valve 535. The remaining plating liquid L1 is heated to the set temperature by the heating unit 536, and maintained at the set temperature by the heating unit 536 and the heat retaining unit 537.

The volume of the plating liquid line 533 on the downstream side of the valve 535 is larger than the amount of the plating liquid L1 used in a subsequent liquid accumulation processing. Thus, in the activation processing, the plating liquid L1 in an amount for at least one cycle of the liquid accumulation processing is heated and kept warm in the plating liquid line 533 on the downstream side of the valve 535.

Upon the completion of the dummy adjustment processing or in the process S101, if the substrate W to be currently processed is not the first one among the plurality of substrates W to be sequentially processed (process S101, No), a carry-in processing is performed in the plating unit 5 (process S103). In the carry-in processing, the substrate W is carried into the chamber 51 by the substrate transfer device 17 and disposed on and held by the chuck member 521 of the substrate holder 52.

Next, in the plating unit 5, an adjustment processing is performed (process S104). In the adjustment processing, the substrate W stands by for a preset time while being kept on the chuck member 521. That is, for the substrate W, a start of a pre-processing, which is a next processing to be performed, is delayed by the preset time.

Thereafter, in the plating unit 5, the pre-processing is performed (process S105). In the pre-processing, the rotation motor 523 is driven to rotate the substrate W at a predetermined rotation number. Then, the nozzle arm 56 located at the retreat position (the position indicated by the solid line in FIG. 2) is moved to the discharge position above the center of the substrate W. Subsequently, the cleaning liquid L2 is supplied from the cleaning liquid nozzle 541 onto the substrate W being rotated, so that the front surface of the substrate W is cleaned. As a result, a deposit or the like adhering to the substrate W is removed from the substrate W. The cleaning liquid L2 supplied onto the substrate W is drained into drain duct 581. Thereafter, the rinse liquid L3 is supplied from the rinse liquid nozzle 551 onto the substrate W being rotated, so that the front surface of the substrate W is rinsed. As a result, the cleaning liquid L2 remaining on the substrate W is washed away. The rinse liquid L3 supplied onto the substrate W is drained into the drain duct 581. In addition, in the pre-processing, the plating unit 5 may further perform a processing of supplying the IPA to the substrate W.

Next, in the plating unit 5, the liquid accumulation processing is performed (process S106). The liquid accumulation processing is a process of supplying the plating liquid L1 activated by being heated and kept at the set temperature to the substrate W after being subjected to the pre-processing, thus allowing the plaiting liquid L to be accumulated on the substrate W.

In this case, the rotation number of the substrate W is first reduced to be smaller than the rotation number in the rinsing processing. For example, the rotation number of the substrate W may be set to be in the range from 50 rpm to 150 rpm. Accordingly, a plating film formed on the substrate W can be made uniform. Alternatively, the rotation of the substrate W may be stopped.

Then, the activated plating liquid L1 is discharged onto the front surface of the substrate W from the plating liquid nozzle 531. The discharged plating liquid L1 stays on the front surface of the substrate W due to surface tension, and this plating liquid L1 is accumulated on the front surface of the substrate W, so that a layer (so-called puddle) of the plating liquid L1 is formed. A part of the plating liquid L1 flows out from the front surface of the substrate W and is drained through the drain duct 581. After a predetermined amount of the plating liquid L1 is discharged from the plating liquid nozzle 531, the discharge of the plating liquid L1 is stopped. Then, the nozzle arm 56 placed at the discharge position is moved to the retreat position.

In the plating unit 5, the activation processing is started in parallel with the liquid accumulation processing. For example, the activation processing is begun at the time when the pump 534 and the valve 535 are operated in the above-described liquid accumulation processing, that is, at the time when the plating liquid L1 of the room temperature is sent from the plating liquid source 532 to the plating liquid line 533 on the downstream side of the valve 535. The activation processing here is a process of activating the plating liquid L1 used for a substrate W to be processed next time.

Subsequently, in the plating unit 5, a plating processing is performed (process S107). The plating processing is a process of forming a plating film by electroless plating on the substrate W by heating the substrate W on which the plating liquid L1 is accumulated.

First, the substrate W is covered by the lid 6. In this case, the revolving motor 72 of the lid moving mechanism 7 is first driven to revolve the lid 6 in the horizontal direction, thus allowing the lid 6 to be located at the upper position (the position indicated by the dashed double-dotted line in FIG. 2).

Then, the cylinder 73 of the lid moving mechanism 7 is driven, so that the lid 6 located at the upper position is lowered and positioned at a first distance position. Accordingly, the distance between the substrate W and the first ceiling plate 611 of the lid 6 becomes a first distance, and the sidewall member 62 of the lid 6 is positioned to surround the substrate W. In the present exemplary embodiment, a lower end 621 of the sidewall member 62 of the lid 6 is located at a position lower than the bottom surface of the substrate W. In this way, the substrate W is covered by the lid 6, and a space around the substrate W is blocked.

After the substrate W is covered by the lid 6, the gas nozzle 661 provided at the ceiling member 61 of the lid 6 discharges the inert gas to the inside of the lid 6. Accordingly, the inside of the lid 6 is replaced with the inert gas, and the vicinity of the substrate W is turned into a low oxygen atmosphere. The inert gas is discharged for a predetermined time, and after the lapse of the predetermined time, the discharge of the inert gas is stopped.

Subsequently, the plating liquid L1 accumulated on the substrate W is heated by the heater 63. When the temperature of the plating liquid L1 rises up to a temperature at which a component of the plating liquid L is precipitated, the component of the plating liquid L1 is precipitated on a front surface of the seed layer to form the plating film thereon.

Then, the lid moving mechanism 7 is driven, and the lid 6 is positioned at the retreat position. In this case, as the cylinder 73 of the lid moving mechanism 7 is first driven, the lid 6 is raised and placed at the upper position. Then, the revolving motor 72 of the lid moving mechanism 7 is driven, so that the lid 6 once located at the upper position is revolved in the horizontal direction and placed at the retreat position.

Next, in the plating unit 5, a post-processing is performed (process S108). In this case, the rotation number of the substrate W is first increased to be higher than the rotation number in the plating processing. Thereafter, the rinse liquid nozzle 551 placed at the retract position is moved to the discharge position. Then, the rinse liquid L3 is supplied from the rinse liquid nozzle 551 onto the substrate W being rotated, so that the front surface of the substrate W is rinsed. Accordingly, the plating liquid L1 remaining on the substrate W is washed away. Further, in the post-processing, the plating unit 5 may sequentially supply not only the rinse liquid L3 but also the cleaning liquid L2 or DIW onto the substrate W.

Subsequently, in the plating unit 5, a drying processing is performed (process S109). In this case, the substrate W is rotated at a high speed by increasing the rotation number of the substrate W to be higher than the rotation number in the post-processing. Accordingly, the rinse liquid L3 remaining on the substrate W is scattered off, and the substrate W is dried. Further, in the drying processing, the plating unit 5 may supply IPA onto the substrate W to replace the processing liquid on the substrate W with the IPA, thus drying the substrate W by using volatilization of the IPA, in addition to the above-described drying by the scattering.

Upon the completion of the drying processing, the substrate W is taken out from the plating unit 5 by the substrate transfer device 17 and transferred to the delivery unit 14. The substrate W transferred to the delivery unit 14 is taken out from the delivery unit 14 by the substrate transfer device 13 and accommodated in the carrier C.

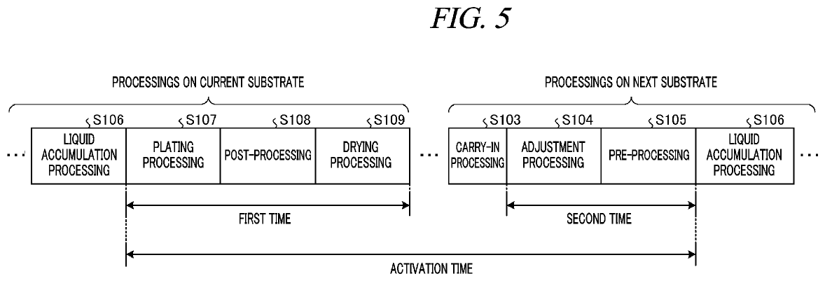

FIG. 5 is an explanatory diagram of the activation processing according to the exemplary embodiment. As shown in FIG. 5, a time required for the activation processing (activation time) is set to be a sum of a time required for the plating processing, the post-processing and the drying processing (first time) and a time required for the adjustment processing and the pre-processing (second time).

A start point of the activation processing for the plating liquid L1 to be used for the substrate W to be processed next is set to be a start point of the plating processing for the substrate W being currently processed. Therefore, the first time of the activation processing for the plating liquid L1 to be used for the next substrate W overlaps with the plating processing, the post-processing and the drying processing for the current substrate W. For this reason, as compared to, for example, a case where the activation processing is started after a series of processings for the next substrate W is begun, a time required for the series of substrate processings can be shortened by as much as the time (first time) required for the plating processing, the post-processing and the drying processing. That is, throughput of the series of substrate processings including the plating processing can be improved.

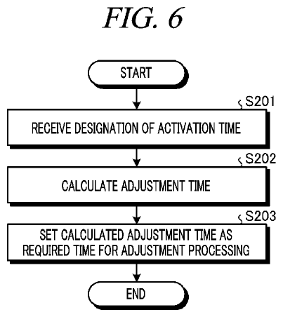

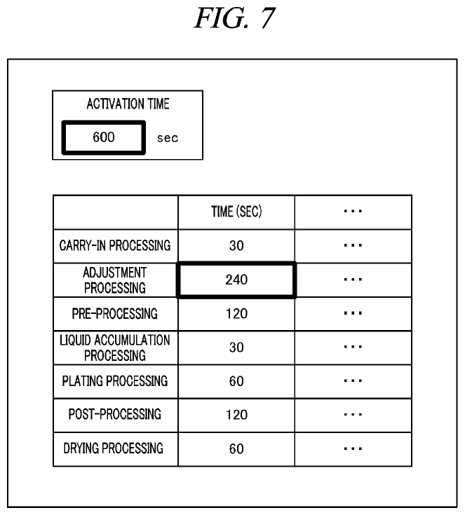

The activation time is designated by, for example, a user of the substrate processing apparatus 1. The controller 91 sets a time required for the adjustment processing (adjustment time) so that the sum of the first time and the second time is equal to the activation time designated by the user. FIG. 6 is a flowchart showing a sequence of an adjustment time setting processing according to the exemplary embodiment. Further, FIG. 7 is diagram illustrating an example of the adjustment time setting processing according to the exemplary embodiment. FIG. 7 also illustrates an example of recipe information and an activation time input field displayed on a non-illustrated display belonging to the control device 9.

As shown in FIG. 6, the controller 91 receives a designation of the activation time by, for example, an input operation to an input device such as a keyboard and a touch panel display provided in the control device 9 (process S201). Here, as shown in FIG. 7, it is assumed that ‘600 sec (seconds)’ is designated as the activation time.

Next, the controller 91 calculates the adjustment time by subtracting the first time and the time required for the pre-processing from the received activation time (process S202).

For example, as shown in FIG. 7, assume that a pre-processing time is set to be ‘120 sec’; a liquid accumulation processing time, ‘30 sec’; a plating processing time, ‘60 sec’; a post-processing time, ‘120 sec’; and a drying processing time, ‘60’ in the recipe information. In this case, the controller 91 calculates the adjustment time ‘240 sec’ by subtracting ‘120 sec’, ‘30 sec’, ‘60 sec’, ‘120 sec’ and ‘60 sec’ from the designated adjustment time ‘600 sec’.

Then, the controller 91 sets the calculated adjustment time ‘240 sec’ in the recipe information as an adjustment processing time (process S203).

As described above, the plating unit 5 according to the exemplary embodiment is capable of automatically adjusting the recipe according to the activation time received from the user. Therefore, in the plating unit 5 according to the exemplary embodiment, the activation time can be calculated easily, and the recipe can be set easily.

In addition, although the present exemplary embodiment has been described for the example where the pre-processing is included in the series of substrate processings, the pre-processing may not need to be included in the series of substrate processings. If the pre-processing is not included in the series of substrate processings, the controller 91 may calculate a time obtained by subtracting the first time from the designated activation time as the adjustment time.

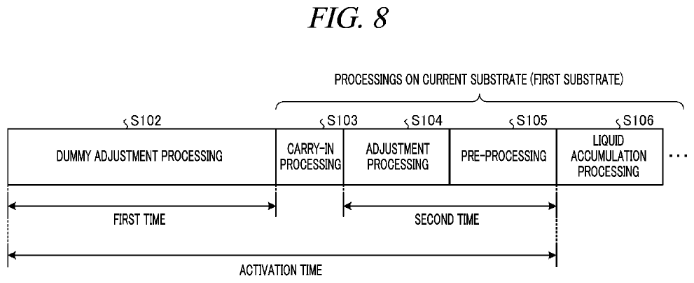

FIG. 8 is an explanatory diagram of the dummy adjustment processing according to the exemplary embodiment. If the substrate W to be processed currently is the first one among the plurality of substrates W to be successively processed, the first time cannot be obtained during the processing of a ‘previous substrate W’ because no ‘previous substrate W’ exists.

Thus, when processing the first one among the plurality of substrates W, the plating unit 5 performs the dummy adjustment processing before starting a processing on the current substrate W, specifically, the carry-in processing. The dummy adjustment processing is, for example, a process in which the substrate W held by the substrate transfer device 17 is made to stand by in front of the plating unit 5 for the first time.

In this way, by performing the dummy adjustment processing, it is possible to secure an appropriate activation time for the plating liquid L1 to be used for the first one of the plurality of substrates W to be processed in succession.

As described above, a substrate processing method according to the exemplary embodiment includes activating (as an example, the activation processing), accumulating a liquid (as an example, the liquid accumulation processing), forming a plating film (as an example, the plating processing), performing a post-processing (as an example, the post-processing), and drying (as an example, the drying processing). In the activating, by heating and maintaining a plating liquid (as an example, the plating liquid L1) at a predetermined temperature, the plating liquid is activated. In the accumulating of the liquid, the activated plating liquid is accumulated on a substrate (as an example, the substrate W). In the forming of the plating film, while heating the substrate on which the plating liquid is accumulated, the plating film is formed on the substrate by electroless plating. In the performing of the post-processing, the post-processing with a liquid (as an example, the rinse liquid L3) is performed on the substrate on which the plating film is formed. In the drying, the substrate after being subjected to the post-processing is dried. In addition, the activating of the plating liquid to be used for a substrate to be processed next is performed in parallel with the forming of the plating film, the performing of the post-processing, and the drying upon the substrate being processed currently.

Accordingly, as compared to a case where the activation processing is started after the beginning of a series of processings upon the next substrate, a time required for the series of substrate processings can be reduced by as much as a time required for the plating processing, the post-processing and the drying processing. Therefore, the throughput of the series of substrate processings including the plating processing can be improved.

Further, the substrate processing method according to the exemplary embodiment may further include receiving and delaying a start (as an example, the adjustment processing). In the receiving, a designation of a required time of the activating of the plating liquid is received. In the delaying of the start, a start of the accumulating of the liquid on the next substrate is delayed based on the required time in the receiving and the time (as an example, the first time) required for the forming of the plating film, the performing of the post-processing and the drying.

Furthermore, the substrate processing method according to the exemplary embodiment may further include performing a pre-processing (as an example, the pre-processing as an example). In the performing of the pre-processing, a pre-processing with a liquid (as an example, the cleaning liquid L2 and the rinse liquid L3) is performed on the substrate before being subjected to the accumulating of the liquid. In this case, in the delaying of the start, the start of the accumulating of the liquid for the next substrate is delayed by as much as the time obtained by subtracting the time of the forming of the plating film, the performing of the post-processing and the drying and the time of the performing of the pre-processing from the required time in the receiving.

Accordingly, since the recipe can be automatically adjusted according to the activation time received from the user, the calculation of the activation time and the setting of the recipe can be carried out easily.

Further, the substrate processing method according to the exemplary embodiment may include delaying the start (as an example, the dummy adjustment processing). In the delaying of the start, the start of the accumulating of the liquid is further delayed by a time equivalent to the time of the forming of the plating film, the performing of the post-processing, and the drying when processing the first one of multiple substrates to be successively processed. Accordingly, an appropriate activation time for the plating liquid to be used for the first one of the multiple substrates to be successively processed can be obtained.

Moreover, a substrate processing apparatus according to the exemplary embodiment (as an example, the plating unit 5) includes an activation unit (as an example, the plating liquid line 533, the heating unit 536, and the heat retaining unit 537); a holder (as an example, the substrate holder 52); a first liquid supply (as an example, the plating liquid supply 53); a heating unit (as an example, the lid 6); a second liquid supply (as an example, the rinse liquid supply 55); and a controller (as an example, the controller 91). The activation unit is configured to activate the plating liquid by heating and maintaining a plating liquid (as an example, the plating liquid L1) at a predetermined temperature. The holder is configured to hold and rotate a substrate (as an example, the substrate W). The first liquid supply is configured to supply the plating liquid activated by the activation unit to the substrate held by the holder. The heating unit is configured to heat the substrate held by the holder. The second liquid supply is configured to supply a processing liquid (as an example, the rinse liquid L3) other than the plating liquid to the substrate held by the holder. The controller is configured to control the activation unit to perform an activation processing of activating the plating liquid; control the first liquid supply to perform a liquid accumulation processing of accumulating the plating liquid activated by the activation unit on the substrate; control the heating unit to perform a plating processing of forming a plating film on the substrate by electroless plating while heating the substrate on which the plating liquid is accumulated; control the second liquid supply to perform a post-processing of liquid-processing the substrate after being subjected to the plating processing; and control the holder to perform a drying processing of drying the substrate after being subjected to the post-processing. Further, the controller performs the activation processing of activating the plating liquid to be used for a next substrate in parallel with the plating processing, the post-processing and the drying processing upon the current substrate.

Therefore, in the substrate processing apparatus according to the exemplary embodiment, the throughput of the series of substrate processings including the plating processing can be improved.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

W: Substrate
1: Substrate processing apparatus
5: Plating unit
6: Lid
9: Control device
51: Chamber
52: Substrate holder
53: Plating liquid supply
54: Cleaning liquid supply
55: Rinse liquid supply
56: Nozzle arm
531: Plating liquid nozzle
532: Plating liquid source
533: Plating liquid line
534: Pump
535: Valve
536: Heating unit
537: Heat retaining unit

1. A substrate processing method, comprising:
activating a plating liquid by previously heating and maintaining the plating liquid at a preset temperature;
accumulating the activated plating liquid on a substrate;
forming a plating film on the substrate by electroless plating while heating the substrate on which the plating liquid is accumulated;
performing a post-processing with a liquid on the substrate on which the plating film is formed; and
drying the substrate after being subjected to the post-processing,
wherein activating the plating liquid for the substrate to be processed next is performed in parallel with the forming of the plating film, the performing of the post-processing, and the drying of the substrate upon the substrate being processed currently.

2. The substrate processing method of claim 1, further comprising:
receiving a designation of a required time of the activating of the plating liquid; and
delaying a start of the accumulating of the activated plating liquid on the substrate to be processed next, based on the required time in the receiving of the designation of the required time and a time taken for the forming of the plating film, the performing of the post-processing and the drying of the substrate.

3. The substrate processing method of claim 2, further comprising:
performing a pre-processing with a liquid on the substrate before being subjected to the accumulating of the plating liquid,
wherein in the delaying of the start, the start of the accumulating of the plating liquid on the substrate to be processed next is delayed by as much as a time calculated by subtracting the time taken for the forming of the plating film, the performing of the post-processing and the drying of the substrate and a time taken for the performing of the pre-processing from the required time in the receiving of the designation of the required time.

4. The substrate processing method of claim 2, further comprising:
delaying, when processing a first one of multiple substrates to be successively processed, the start of the accumulating of the plating liquid by a time equivalent to the time taken for the forming of the plating film, the performing of the post-processing and the drying of the substrate.

5. A substrate processing apparatus, comprising:
an activation unit configured to activate a plating liquid by previously heating and maintaining the plating liquid at a preset temperature;
a holder configured to hold and rotate a substrate;
a first liquid supply configured to supply the plating liquid activated by the activation unit to the substrate held by the holder;
a heating unit configured to heat the substrate held by the holder;
a second liquid supply configured to supply a processing liquid other than the plating liquid to the substrate held by the holder; and
a controller configured to control the activation unit to perform an activation processing of activating the plating liquid, control the first liquid supply to perform a liquid accumulation processing of accumulating the plating liquid activated by the activation unit on the substrate, control the heating unit to perform a plating processing of forming a plating film on the substrate by electroless plating while heating the substrate on which the plating liquid is accumulated, control the second liquid supply to perform a post-processing of liquid-processing the substrate after being subjected to the plating processing, and control the holder to perform a drying processing of drying the substrate after being subjected to the post-processing,
wherein the controller performs the activation processing of activating the plating liquid for the substrate to be processed next in parallel with the plating processing, the post-processing and the drying processing on the substrate being processed currently.
